(19) United States
(12) Patent Application Publication
(10) Pub. No.: US 2015/0262632 A1
(43) Pub. Date: Sep. 17, 2015

(54) GROUPING STORAGE PORTS BASED ON DISTANCE

(71) Applicant: Fusion-io, Inc., Salt Lake City, UT (US)

(72) Inventors: Lance Shelton, San Jose, CA (US); John Cagle, Holladay, UT (US)

(21) Appl. No.: 14/280,564

(22) Filed: May 16, 2014

Related U.S. Application Data
(60) Provisional application No. 61/951,944, filed on Mar. 12, 2014.

(51) Int. Cl. G11C 7/10; G06F 12/02

(52) U.S. Cl. CPC G11C 7/1075; G06F 12/0246; G06F 2212/7201; G06F 2212/2542

(57) ABSTRACT

Apparatuses, systems, methods, and computer program products are disclosed for grouping storage ports based on distance. A distance module may be configured to assign distance values to a plurality of ports. Distance values may be for data communications between a node and ports. A group module may be configured to assign one or more ports of a plurality of ports to one of a first port group and a second port group based on assigned distances. A selection module may be configured to select a second port group for data communications between a node and a non-volatile storage medium in response to a first port group being unavailable.

### CROSS-REFERENCES TO RELATED APPLICATIONS

This application claims the benefit of U.S. Provisional Patent Application No. 61/951,944 entitled “GROUPING STORAGE PORTS BASED ON DISTANCE” and filed on Mar. 12, 2014 for Lance Shelton, which is incorporated herein by reference.

### TECHNICAL FIELD

The present disclosure, in various embodiments, relates to computer storage and more particularly relates to grouping storage ports based on distances.

### BACKGROUND

Storage or memory may be exported or accessible through multiple ports or other interfaces. Different storage volumes, blocks of memory ports, or the like may have different performance characteristics for different storage targets, such as a non-uniform memory access (NUMA) nodes or the like.

Data may be transferred between a port and a non-volatile storage volume, block of memory, or the like, which may be local or remote to a NUMA node or other target associated with the port. Access performance may be impacted by the distance between a target port and a non-volatile storage volume, block of memory, or the like. Therefore, grouping together ports with different distances using the ports equally to access a storage volume, memory, or the like may introduce latency or delay in the access.

### SUMMARY

Methods are presented for grouping storage ports based on distance. In one embodiment, a method includes determining a plurality of ports through which a non-volatile storage volume is accessible. In another embodiment, a method includes determining distances between a processor node and a plurality of ports. In a further embodiment, a method includes assigning ports to a plurality of groups based on determined distances. In certain embodiments, a plurality of groups have different priorities for a processor node.

Apparatuses are presented for grouping storage ports based on distance. In one embodiment, a distance module is configured to assign distance values to a plurality of ports. Distance values, in certain embodiments, are for data communications between a node and a plurality of ports. A node, in one embodiment, may comprise one of a plurality of nodes. In a further embodiment, a group module is configured to assign one or more ports of a plurality of ports to one of a local port group and a remote port group based on assigned distances. A selection module, in another embodiment, is configured to select a remote port group for data communications between a node and a non-volatile storage medium in response to a local port group being unavailable.

An apparatus, in another embodiment, includes means for determining numbers of hops for a plurality of paths between a non-uniform memory access (NUMA) node and a storage medium. In a further embodiment, an apparatus includes means for grouping paths for a NUMA node based on determined numbers of hops. Paths, in one embodiment, are assigned to one of a first port group and a second port group using an asymmetric logical unit access (ALUA) protocol. An apparatus, in certain embodiments, includes means for accessing a storage medium using one or more paths so that a path of a first port group is selected for accessing the storage medium before a path of second port group.

Computer program products are presented comprising a computer readable storage medium storing computer usable program code executable to perform operations for grouping storage ports based on distance. In one embodiment, an operation includes determining distances between a first processor of a computing system and a plurality of ports and between a second processor of the computing system and the plurality of ports. An operation, in a further embodiment, includes assigning ports to a set of groups for a first processor based on determined distances so that the set of groups has different priorities for the first processor. In another embodiment, an operation includes assigning ports to a different set of groups for a second processor based on determined distances so that the different set of groups having different priorities for the second processor.

### BRIEF DESCRIPTION OF THE DRAWINGS

In order that the advantages of the disclosure will be readily understood, a more particular description of the disclosure briefly described above will be rendered by reference to specific embodiments that are illustrated in the appended drawings. Understanding that these drawings depict only typical embodiments of the disclosure and are not therefore to be considered to be limiting of its scope, the disclosure will be described and explained with additional specificity and detail through the use of the accompanying drawings, in which:

FIG. 1 is a schematic block diagram illustrating one embodiment of a system for grouping storage ports based on distances;

FIG. 2 is a schematic block diagram illustrating one embodiment of a module for grouping storage ports based on distances;

FIG. 3 is a schematic block diagram illustrating one embodiment of another module for grouping storage ports based on distances;

FIG. 4A is a schematic block diagram illustrating one embodiment of a system for grouping storage ports based on distances;

FIG. 4B is a schematic block diagram illustrating one embodiment of another system for grouping storage ports based on distances;

FIG. 4C is a schematic block diagram illustrating one embodiment of a system for grouping storage ports based on distances;

FIG. 5 is a schematic flow chart diagram illustrating one embodiment of a method for grouping storage ports based on distances; and

FIG. 6 is a schematic flow chart diagram illustrating one embodiment of another method for grouping storage ports based on distances.

### DETAILED DESCRIPTION

Aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable storage media having computer readable program code embodied thereon.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network. Where a module or portions of a module are implemented in software, the software portions are stored on one or more computer readable storage media.

Any combination of one or more computer readable storage media may be utilized. A computer readable storage medium may be, for example, but not limited to, an electronic, magnetic, optical, electromagnetic, infrared, or semiconductor system, apparatus, or device, or any suitable combination of the foregoing.

More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), phase change memory (PRAM or PCM), a portable compact disc read-only memory (CD-ROM), a digital versatile disc (DVD), a blu-ray disc, an optical storage device, a magnetic tape, a Bernoulli drive, a magnetic disk, a magnetic storage device, a punch card, integrated circuits, other digital processing apparatus memory devices, or any suitable combination of the foregoing, but would not include propagating signals. In the context of this document, a computer readable storage medium may be any tangible medium that can contain, or store a program for use by or in connection with an instruction execution system, apparatus, or device.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, structures, or characteristics of the disclosure may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the disclosure. However, the disclosure may be practiced without one or more of the specific details, or with other methods, components, materials, and so forth. In other instances, well-known structures, materials, or operations are not shown or described in detail to avoid obscuring aspects of the disclosure.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

These computer program instructions may also be stored in a computer readable storage medium that can direct a computer, other programmable data processing apparatus, or other devices to function in a particular manner, such that the instructions stored in the computer readable storage medium produce an article of manufacture including instructions which implement the function/act specified in the schematic flowchart diagrams and/or schematic block diagrams block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and computer program products according to various embodiments of the present disclosure. In this regard, each block in the schematic flowchart diagrams and/or schematic block diagrams may represent a module, segment, or portion of code, which comprises one or more executable instructions for implementing the specified logical function(s).

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and computer instructions.

The description of elements in each figure may refer to elements of proceeding figures. Like numbers refer to like elements in all figures, including alternate embodiments of like elements.

According to various embodiments, a non-volatile memory controller manages one or more non-volatile memory devices. The non-volatile memory device(s) may comprise memory or storage devices, such as solid-state storage device(s), that are arranged and/or partitioned into a plurality of addressable media storage locations. As used herein, a media storage location refers to any physical unit of memory (e.g., any quantity of physical storage media on a non-volatile memory device). Memory units may include, but are not limited to: pages, memory divisions, erase blocks, sectors, blocks, collections or sets of physical storage locations (e.g., logical pages, logical erase blocks, described below), or the like.

The non-volatile memory controller may comprise a storage management layer (SML), which may present a logical address space to one or more storage clients. One example of an SML is the Virtual Storage Layer® of Fusion-io, Inc. of Salt Lake City, Utah. Alternatively, each non-volatile memory device may comprise a non-volatile memory media controller, which may present a logical address space to the storage clients. As used herein, a logical address space refers to a logical representation of memory resources. The logical address space may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

The SML may maintain metadata, such as a forward index, to map logical addresses of the logical address space to media storage locations on the non-volatile memory device(s). The SML may provide for arbitrary, any-to-any mappings from logical addresses to physical storage resources. As used herein, an “any-to any” mapping may map any logical address to any physical storage resource. Accordingly, there may be no pre-defined and/or pre-set mappings between logical addresses and particular, media storage locations and/or media addresses. As used herein, a media address refers to an address of a memory resource that uniquely identifies one memory resource from another to a controller that manages a plurality of memory resources. By way of example, a media address includes, but is not limited to: the address of a media storage location, a physical memory unit, a collection of physical memory units (e.g., a logical memory unit), a portion of a memory unit (e.g., a logical memory unit address and offset, range, and/or extent), or the like. Accordingly, the SML may map logical addresses to physical data resources of any size and/or granularity, which may or may not correspond to the underlying data partitioning scheme of the non-volatile memory device(s). For example, in some embodiments, the non-volatile memory controller is configured to store data within logical memory units that are formed by logically combining a plurality of physical memory units, which may allow the non-volatile memory controller to support many different virtual memory unit sizes and/or granularities.

As used herein, a logical memory element refers to a set of two or more non-volatile memory elements that are or are capable of being managed in parallel (e.g., via an I/O and/or control bus). A logical memory element may comprise a plurality of logical memory units, such as logical pages, logical memory divisions (e.g., logical erase blocks), and so on. As used herein, a logical memory unit refers to a logical construct combining two or more physical memory units, each physical memory unit on a respective non-volatile memory element in the respective logical memory element (each non-volatile memory element being accessible in parallel). As used herein, a logical memory division refers to a set of two or more physical memory divisions, each physical memory division on a respective non-volatile memory element in the respective logical memory element.

The logical address space presented by the storage management layer may have a logical capacity, which may correspond to the number of available logical addresses in the logical address space and the size (or granularity) of the data referenced by the logical addresses. For example, the logical capacity of a logical address space comprising 2̂32 unique logical addresses, each referencing 2048 bytes (2 KiB) of data may be 2̂43 bytes. (As used herein, a kibibyte (KiB) refers to 1024 bytes). In some embodiments, the logical address space may be thinly provisioned. As used herein, a “thinly provisioned” logical address space refers to a logical address space having a logical capacity that exceeds the physical capacity of the underlying non-volatile memory device(s). For example, the storage management layer may present a 64-bit logical address space to the storage clients (e.g., a logical address space referenced by 64-bit logical addresses), which exceeds the physical capacity of the underlying non-volatile memory devices. The large logical address space may allow storage clients to allocate and/or reference contiguous ranges of logical addresses, while reducing the chance of naming conflicts. The storage management layer may leverage the any-to-any mappings between logical addresses and physical storage resources to manage the logical address space independently of the underlying physical storage devices. For example, the storage management layer may add and/or remove physical storage resources seamlessly, as needed, and without changing the logical addresses used by the storage clients.

The non-volatile memory controller may be configured to store data in a contextual format. As used herein, a contextual format refers to a self-describing data format in which persistent contextual metadata is stored with the data on the physical storage media. The persistent contextual metadata provides context for the data it is stored with. In certain embodiments, the persistent contextual metadata uniquely identifies the data that the persistent contextual metadata is stored with. For example, the persistent contextual metadata may uniquely identify a sector of data owned by a storage client from other sectors of data owned by the storage client. In a further embodiment, the persistent contextual metadata identifies an operation that is performed on the data. In a further embodiment, the persistent contextual metadata identifies a sequence of operations performed on the data. In a further embodiment, the persistent contextual metadata identifies security controls, a data type, or other attributes of the data. In a certain embodiment, the persistent contextual metadata identifies at least one of a plurality of aspects, including data type, a unique data identifier, an operation, and a sequence of operations performed on the data. The persistent contextual metadata may include, but is not limited to: a logical address of the data, an identifier of the data (e.g., a file name, object id, label, unique identifier, or the like), reference(s) to other data (e.g., an indicator that the data is associated with other data), a relative position or offset of the data with respect to other data (e.g., file offset, etc.), data size and/or range, and the like. The contextual data format may comprise a packet format comprising a data segment and one or more headers. Alternatively, a contextual data format may associate data with context information in other ways (e.g., in a dedicated index on the non-volatile memory media, a memory division index, or the like).

In some embodiments, the contextual data format may allow data context to be determined (and/or reconstructed) based upon the contents of the non-volatile memory media, and independently of other metadata, such as the arbitrary, any-to-any mappings discussed above. Since the media location of data is independent of the logical address of the data, it may be inefficient (or impossible) to determine the context of data based solely upon the media location or media address of the data. Storing data in a contextual format on the non-volatile memory media may allow data context to be determined without reference to other metadata. For example, the contextual data format may allow the metadata to be reconstructed based only upon the contents of the non-volatile memory media (e.g., reconstruct the any-to-any mappings between logical addresses and media locations).

In some embodiments, the non-volatile memory controller may be configured to store data on one or more asymmetric, write-once media, such as solid-state storage media. As used herein, a “write once” storage medium refers to a storage medium that is reinitialized (e.g., erased) each time new data is written or programmed thereon. As used herein, an “asymmetric” storage medium refers to a storage medium having different latencies for different storage operations. Many types of solid-state storage media are asymmetric; for example, a read operation may be much faster than a write/program operation, and a write/program operation may be much faster than an erase operation (e.g., reading the media may be hundreds of times faster than erasing, and tens of times faster than programming the media). The memory media may be partitioned into memory divisions that can be erased as a group (e.g., erase blocks) in order to, inter alia, account for the asymmetric properties of the media. As such, modifying a single data segment in-place may require erasing the entire erase block comprising the data, and rewriting the modified data to the erase block, along with the original, unchanged data. This may result in inefficient “write amplification,” which may excessively wear the media. Therefore, in some embodiments, the non-volatile memory controller may be configured to write data out-of-place. As used herein, writing data “out-of-place” refers to writing data to different media storage location(s) rather than overwriting the data “in-place” (e.g., overwriting the original physical location of the data). Modifying data out-of-place may avoid write amplification, since existing, valid data on the erase block with the data to be modified need not be erased and recopied. Moreover, writing data out-of-place may remove erasure from the latency path of many storage operations (the erasure latency is no longer part of the critical path of a write operation).

The non-volatile memory controller may comprise one or more processes that operate outside of the regular path for servicing of storage operations (the “path” for performing a storage operation and/or servicing a storage request). As used herein, the “path for servicing a storage request” or “path for servicing a storage operation” (also referred to as the “critical path”) refers to a series of processing operations needed to service the storage operation or request, such as a read, write, modify, or the like. The path for servicing a storage request may comprise receiving the request from a storage client, identifying the logical addresses of the request, performing one or more storage operations on non-volatile memory media, and returning a result, such as acknowledgement or data. Processes that occur outside of the path for servicing storage requests may include, but are not limited to: a groomer, de-duplication, and so on. These processes may be implemented autonomously and in the background, so that they do not interfere with or impact the performance of other storage operations and/or requests. Accordingly, these processes may operate independent of servicing storage requests.

In some embodiments, the non-volatile memory controller comprises a groomer, which is configured to reclaim memory divisions (e.g., erase blocks) for reuse. The write out-of-place paradigm implemented by the non-volatile memory controller may result in obsolete or invalid data remaining on the non-volatile memory media. For example, overwriting data X with data Y may result in storing Y on a new memory division (rather than overwriting X in place), and updating the any-to-any mappings of the metadata to identify Y as the valid, up-to-date version of the data. The obsolete version of the data X may be marked as invalid, but may not be immediately removed (e.g., erased), since, as discussed above, erasing X may involve erasing an entire memory division, which is a time-consuming operation and may result in write amplification. Similarly, data that is no longer is use (e.g., deleted or trimmed data) may not be immediately removed. The non-volatile memory media may accumulate a significant amount of invalid data. A groomer process may operate outside of the critical path for servicing storage operations. The groomer process may reclaim memory divisions so that they can be reused for other storage operations. As used herein, reclaiming a memory division refers to erasing the memory division so that new data may be stored/programmed thereon. Reclaiming a memory division may comprise relocating valid data on the memory division to a new location. The groomer may identify memory divisions for reclamation based upon one or more factors, which may include, but are not limited to: the amount of invalid data in the memory division, the amount of valid data in the memory division, wear on the memory division (e.g., number of erase cycles), time since the memory division was programmed or refreshed, and so on.

The non-volatile memory controller may be further configured to store data in a log format. As described above, a log format refers to a data format that defines an ordered sequence of storage operations performed on a non-volatile memory media. In some embodiments, the log format comprises storing data in a pre-determined sequence of media addresses of the non-volatile memory media (e.g., within sequential pages and/or erase blocks of the media). The log format may further comprise associating data (e.g., each packet or data segment) with respective sequence indicators. The sequence indicators may be applied to data individually (e.g., applied to each data packet) and/or to data groupings (e.g., packets stored sequentially on a memory division, such as an erase block). In some embodiments, sequence indicators may be applied to memory divisions when the memory divisions are reclaimed (e.g., erased), as described above, and/or when the memory divisions are first used to store data.

In some embodiments the log format may comprise storing data in an “append only” paradigm. The non-volatile memory controller may maintain a current append point at a media address of the non-volatile memory device. The append point may be a current memory division and/or offset within a memory division. Data may then be sequentially appended from the append point. The sequential ordering of the data, therefore, may be determined based upon the sequence indicator of the memory division of the data in combination with the sequence of the data within the memory division. Upon reaching the end of a memory division, the non-volatile memory controller may identify the “next” available memory division (the next memory division that is initialized and ready to store data). The groomer may reclaim memory divisions comprising invalid, stale, and/or deleted data, to ensure that data may continue to be appended to the media log.

The log format described herein may allow valid data to be distinguished from invalid data based upon the contents of the non-volatile memory media, and independently of other metadata. As discussed above, invalid data may not be removed from the non-volatile memory media until the memory division comprising the data is reclaimed. Therefore, multiple “versions” of data having the same context may exist on the non-volatile memory media (e.g., multiple versions of data having the same logical addresses). The sequence indicators associated with the data may be used to distinguish invalid versions of data from the current, up-to-date version of the data; the data that is the most recent in the log is the current version, and previous versions may be identified as invalid.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description.

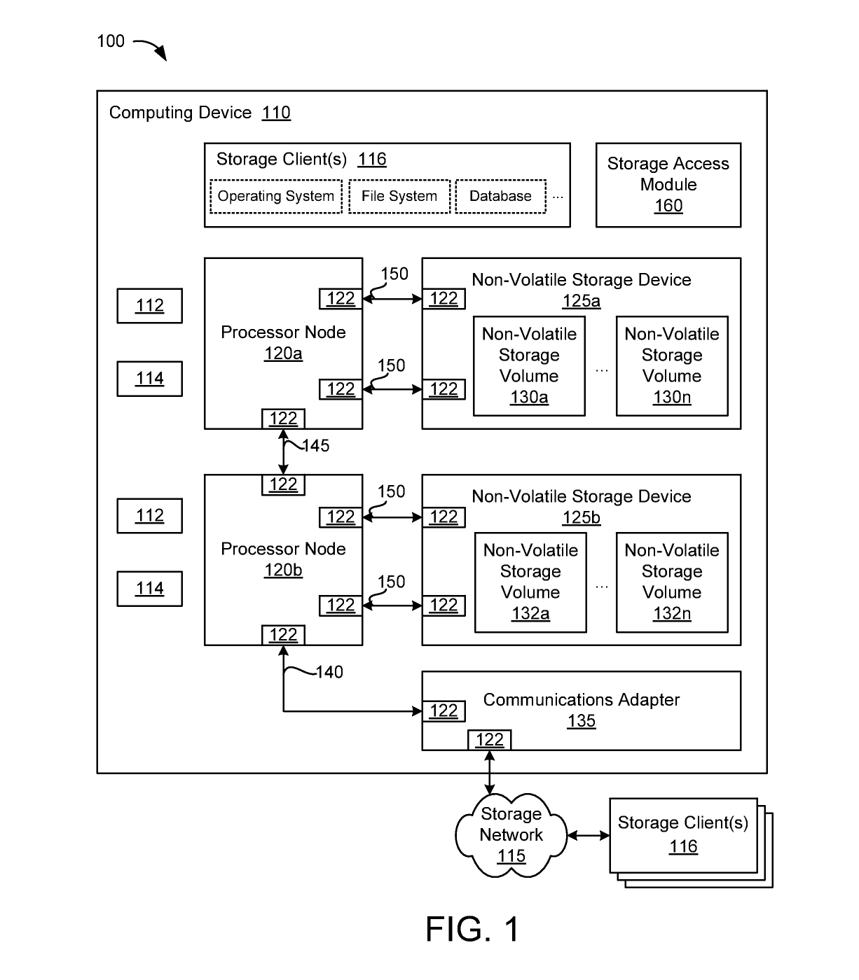

FIG. 1 depicts one embodiment of a system 100 comprising a storage access module 160. The storage access module 160 may be part of and/or in communication with one or more processor nodes 120a-b, one or more non-volatile storage devices 125a-b, and/or one or more communications adapters 135. In one embodiment, the processor nodes 120a-b each comprise one or more processors. A processor may comprise one or more central processing units (CPUs), one or more general-purpose processors, one or more application-specific processors, one or more virtual processors (e.g., the computing device 110 may be a virtual machine operating within a host), one or more processor cores, an application specific integrated circuit (ASIC), another integrated circuit device, a controller, a micro-processor, or the like. A processor node 120a-b, in certain embodiments, may include volatile memory 112, one or more input/output (I/O) channels or ports 122, or the like associated with a processor (e.g., that are on the same physical bus as the volatile memory or the like). For example, in one embodiment, a processor node 120a-b may include a block of volatile memory 112 and one or more ports 122 associated with a processor but may not include the processor itself. In a further embodiment, a processor node 120a-b may include a processor itself and a volatile memory 112, one or more ports 122, or the like associated with or local to the processor. Although FIG. 1 depicts two processor nodes 120a-b for clarity, in other embodiments, another number of processor nodes 120a-b may be included in the computing device 110 (e.g., more than two nodes 120a-b, four nodes 120a-b, eight nodes 120a-b, sixteen nodes 120a-b, thirty-two nodes 120a-b, sixty-four nodes 120a-b, or more).

The processor nodes 120a-b may each be associated with or include a volatile memory 112, a non-transitory, computer readable storage media 114, and/or one or more ports 122. The computer readable storage media 114 may comprise executable instructions configured to cause the computing device 110 (e.g., a processor of a processor node 120a-b) to perform steps of one or more of the methods disclosed herein. Alternatively, or in addition, one or more modules associated with the storage access module 160 may be embodied as one or more computer readable instructions stored on the non-transitory storage media 114.

In some embodiments, the processor nodes 120a-b comprise non-uniform memory access (NUMA) nodes 120a-b. In certain embodiments, the computing device 110 includes a plurality of NUMA nodes 120a-b. As used herein, NUMA is a scalable computer memory architecture that is typically used in a multi-processor system. A NUMA node 120a-b may include one or more processors, with each processor having separate memory 112, I/O channels or ports 122, or the like. In certain embodiments, each NUMA node 120a-b is associated with a different system bus. Each processor of a NUMA node 120a-b, in some embodiments, may access memory 112 associated with a different NUMA node 120a-b in a cache coherent manner. In one embodiment, under NUMA, a processor accesses its own local memory 112 (e.g., memory on the same NUMA node 120a-b as the processor) faster than non-local (remote) memory 112 (e.g., memory 112 local to a processor of another NUMA node 120a-b, memory 112 shared between processors of different NUMA nodes 120a-b, or the like).

In some embodiments, the NUMA architecture includes a cache coherent NUMA architecture (ccNUMA), which uses inter-process communication between cache controllers associated with each NUMA node 120a-b in order to maintain a consistent memory image when more than one cache stores the same memory location. In some embodiments, NUMA is implemented either in NUMA-enabled hardware (e.g., such as Intel's® Nehalem and Tukwila processors, AMD's® Opteron® processors, or the like), in software (e.g., such as Microsoft's® SQL Server®), or in some combination of both. While NUMA is primarily described herein, this disclosure applies equally to a symmetric multi-processing (SMP) architecture, a cluster computing architecture, a cache-only memory architecture (COMA), a distributed memory architecture, a shared memory system, a distributed shared memory architecture, a massively parallel processor (MPP) architecture, a grid computing architecture, or other multi-processor computer system or network.

In one embodiment, processors of different processor nodes 120a-b communicate using a processor interconnect bus 145. Although one processor interconnect bus 145 is depicted in FIG. 1, the number of processor interconnect busses 145 may be dependent on the number of processors within each processor node 120a-b, with one processor interconnect bus 145 being used for each possible connection between processors. In certain embodiments, the processor interconnect bus 145 includes a QuickPath Interconnect (QPI) by Intel®, a HyperTransport® bus by AMD®, or the like. In some embodiments, the processor interconnect bus 145 is a high-speed point-to-point interconnect that includes, but is not limited to: a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network, Infiniband, SCSI RDMA, or the like.

In one embodiment, the processor interconnect bus 145 connects a processor to an I/O hub (not shown). In certain embodiments, the I/O hub may be connected to one or more non-volatile storage devices 125a-b, other processor nodes 120a-b, a communications adapter 135, volatile memory 112, a computer readable storage medium 114, and/or the like. In such an embodiment, a processor may access other components of the computing device 110 through the I/O hub. For example, processor node 120a may access the non-volatile storage volumes 132a-n of non-volatile storage device 125b through processor node 120b using the processor interconnect bus 145.

In another embodiment, the computing device 110 includes one or more non-volatile storage devices 125a-b. The non-volatile storage devices 125a-b may comprise non-volatile and/or volatile memory media, such as one or more of NAND flash memory, NOR flash memory, nano random access memory (“nano RAM or NRAM”), nanocrystal wire-based memory, silicon-oxide based sub-10 nanometer process memory, graphene memory, Silicon-Oxide-Nitride-Oxide-Silicon (“SONOS”), resistive RAM (“RRAM”), programmable metallization cell (“PMC”), conductive-bridging RAM (“CBRAM”), magneto-resistive RAM (“MRAM”), dynamic RAM (“DRAM”), phase change RAM (“PRAM or PCM”), magnetic storage media (e.g., hard disk, tape), optical storage media, or the like. While the non-volatile storage devices 125a-b and associated storage media are referred to primarily herein as “storage device” and “storage media,” in various embodiments, the non-volatile storage media may more generally comprise a non-volatile recording media capable of recording data, which may be referred to as a non-volatile memory media, a non-volatile storage media, or the like. Further, the one or more non-volatile storage devices 125a-b, in various embodiments, may comprise a non-volatile recording device, a non-volatile memory device, a non-volatile storage device, or the like.

The non-volatile storage media may comprise one or more non-volatile storage elements, which may include, but are not limited to: chips, packages, planes, die, and the like. A non-volatile storage media controller may be configured to manage storage operations on the non-volatile storage media, and may comprise one or more processors, programmable processors (e.g., field-programmable gate arrays), or the like. In some embodiments, the non-volatile storage media controller is configured to store data on (and read data from) the non-volatile storage media in the contextual, log format described above, and to transfer data to/from a non-volatile storage device 125a-b, and so on.

The storage devices 125a-b may include one or more types of non-volatile and/or volatile memory devices, such as a solid-state storage device, a hard drive, a storage area network (SAN) storage resource, a dual inline memory module (DIMM), a non-volatile DIMM (NVDIMM) comprising volatile memory backed by non-volatile memory, or the like. The storage devices 125a-b may comprise respective storage media controllers and/or storage media. Although the one or more storage devices 125a-b are primarily described herein as non-volatile, in certain embodiments, the one or more storage devices 125a-b may comprise volatile memory media, instead of or in addition to non-volatile storage media. For example, in certain embodiments, the storage devices 125a-b may include one or more of RAM, dynamic RAM (DRAM), static RAM (SRAM), synchronous DRAM (SDRAM), double data rate (DDR) SDRAM, or the like.

The computing device 110 may further comprise a non-volatile storage device interface (not shown) configured to transfer data, commands, and/or queries to the non-volatile storage devices 125a-b over a bus 150, which may be substantially similar to the processor interconnect bus 145 or the like. The non-volatile storage device interface may communicate with the non-volatile storage devices 125a-b using input-output control (IO-CTL) command(s), IO-CTL command extension(s), remote direct memory access, or the like. In a further embodiment, a storage device 125a-b (e.g., non-volatile and/or volatile storage or memory) may be disposed on a memory bus of a processor node 120a-b, or the like, in communication with the processor node 120a-b through a port 122 connected to the memory bus.

The non-volatile storage devices 125a-b, in another embodiment, include one or more non-volatile storage volumes 130a-n, 132a-n. In one embodiment, a non-volatile storage device 125a-b is divided into one or more non-volatile storage volumes 130a-n, 132a-n, which may include one or more logical or physical volumes or partitions. A volume, as used herein, may comprise a logical or physical unit or grouping of storage, memory, and/or data. In certain embodiments, a non-volatile storage volume 130a-n, 132a-n comprises a file system and/or is formatted for use by a particular file system, such as a new technology file system (NTFS), a file allocation table (FAT) file system, an extended file system (e.g., ext, ext2, ext3, ext4), a hierarchical file system (HFS), ZFS, a Reiser file system, or the like. In certain embodiments, a non-volatile storage volume 130a-n, 132a-n includes logical partitions that mirror the underlying physical volume of the non-volatile storage devices 125a-b.

In another embodiment, the non-volatile storage volumes 130a-n, 132a-n include logical partitions that are located on a plurality of non-volatile storage devices 125a-b. In some embodiments, a non-volatile storage manager allocates one or more non-volatile storage volumes 130a-n, 132a-n of the non-volatile storage devices 125a-b. In certain embodiments, the storage manager creates, deletes, concatenates, stripes together, or otherwise modifies one or more non-volatile storage volumes 130a-n, 132a-n. For example, the non-volatile storage devices 125a-b may be striped such that consecutive segments of logically sequential data are stored on different non-volatile storage devices 125a-b.

In another example, the non-volatile storage devices 125a-b may be configured as a redundant array of independent disks (RAID) that is partitioned into several separate non-volatile storage volumes 130a-n, 132a-n. In a small computer system interface (SCSI) configuration, the RAID may include a plurality of SCSI ports 122 that each have a target address assigned. A SCSI target may provide a logical unit number (LUN) that represents each non-volatile storage volume 130a-n, 132a-n of the non-volatile storage devices 125a-b. Multiple non-volatile storage volumes 130a-n, 132a-n may be provided on a SCSI target, which may provide multiple logical units representing the non-volatile storage volumes 130a-n, 132a-n. Thus, in order to access a non-volatile storage volume 130a-n, 132a-n, a device may provide a LUN or other identifier associated with the non-volatile storage volume 130a-n, 132a-n. In certain embodiments, a device requesting access to the non-volatile storage volume 130a-n, 132a-n specifies a port 122 associated with a non-volatile storage volume 130a-n, 132a-n.

Similarly, in another example, a single non-volatile storage device 125a-b may have one physical SCSI port 122. The single non-volatile storage device 125a-b may provide a single SCSI target with a single LUN that may be represented by the value zero. In such an embodiment, the LUN would represent the entire storage of the non-volatile storage device 125a-b. Thus, a LUN may refer to an entire RAID set, a single disk or partition, multiple disks or partitions, or the like. In another embodiment, other standards, in addition to SCSI, for physically connecting and transferring data between computers and peripheral devices may be included, such as Fibre Channel (FC), Internet SCSI (iSCSI), or the like.

In one embodiment, the computing device 110 includes a plurality of ports 122 that facilitate data transfers between computing device 110 components. As used herein, a port comprises a logical or physical access point for data. A physical port may comprise one or more electrical, optical, and/or mechanical connections for transferring data. A logical port may comprise an identifier, an interface (e.g., an application programming interface (API), a shared library, or the like), whereby data may be accessed.

A port 122 may comprise a data access point for a processor node 120a, a non-volatile storage device 125a-b, and/or a communications adapter 135. In one embodiment, each port 122 may be associated with a port identifier that other devices use to request and/or send data through the port 122. For example, the ports 122, as described above, may include SCSI ports 122 that facilitate data transfers between an initiator and a target. As used herein, an initiator, such as a client computer, is the endpoint that initiates a SCSI session. A target, such as a data storage device 125a-b, is the endpoint that does not initiate sessions, but waits for commands sent by an initiator and provides I/O data transfers. In some embodiments, the target provides one or more LUNs to an initiator to commence data transfer between the initiator and the target. In order for an initiator to receive information from a non-volatile storage volume 130a-n of a non-volatile storage device 125a, the initiator may specify a port identifier for the desired non-volatile storage volume 130a-n, or the like.

The computing device 110, in the depicted embodiment, includes a storage access module 160. The storage access module 160, in one embodiment, is configured to determine a plurality of ports 122 through which a non-volatile storage volume 130a-n, 132a-n is accessible, determine distances between a processor node 120a-b and the ports 122, and assign the ports 122 to a plurality of groups based on the determined distances. In certain embodiments, the groups of ports 122 have different usage priorities for the processor node 120a-b. As used herein, a usage priority may include a setting, characteristic, attribute, likelihood, weight, preference, or the like that indicates whether a port 122 or path associated with a processor node 120a-b, a storage device 125a-b, and/or a storage volume 130a-n, 132a-n, will be used in comparison to a different port 122 or path.

For example, a group of local ports 122 for a processor node 120a may have a higher usage priority than a group of remote ports 122 for the processor node 120a. In this example, the usage priority for the local port group may include a setting, such as “optimized,” “active,” “preferred,” or the like, which may indicate that a non-volatile storage volume 130a-n, 132a-n being accessed via processor node 120a should be accessed using the local port group because it has a higher usage priority than the remote port group. Conversely, in the example, the usage priority for the remote port group may include a setting, such as “non-optimized,” “non-preferred,” “standby,” “unavailable,” or the like, which may indicate that the remote port group has a lower usage priority than the local port group and should not be used unless the local port group fails or is otherwise unavailable. The storage access module 160, in certain embodiments, may set different states, usage priorities, or preferences for different groups of ports 122 using an asymmetric logical unit access (ALUA) protocol, such as a “preferred” state, a “non-preferred” state, an “active/optimized” state, an “active/non-optimized” state, a “standby” state, an “unavailable” state, or the like, as described below. In this manner, the storage access module 160, in certain embodiments, may specify optimal ports 122 or associated paths and non-optimal ports 122 or associated paths, in terms of overhead, latency, bandwidth, or the like, associated with a non-volatile storage volume 130a-n, 132a-n. The storage access module 160 may then determine which ports 122 to use, based on the port groupings, in response to a processor node 120a-b, a storage client 116, a device, or the like requesting access to a non-volatile storage volume 130a-n, 132a-n.

In certain embodiments, the storage access module 160 is configured to determine a plurality of ports 122 through which a volatile or non-volatile cache associated with a non-volatile storage volume 130a-n, 132a-n may be accessed, such as a volatile random access memory (RAM) cache (e.g., for NAND flash, for a hard disk drive, or other non-volatile storage), a non-volatile cache (e.g., a NAND flash cache for a slower hard disk drive or other non-volatile storage), or the like. In such an embodiment, each cache for a non-volatile storage volume 130a-n, 132a-n may be associated with (e.g., directly accessible to) a processor node 120a-b, or more particularly, with one or more ports 122 of a processor node 120a-b. In certain embodiments, the storage access module 160 is configured to determine a plurality of ports 122 through which a cache unit is accessible, determine distances between a processor node 120a-b and the ports 122, and assign the ports 122 to a plurality of groups based on the determined distances. In some embodiments, the storage access module 160 uses an ALUA protocol to group the ports 122 and route access to a cache unit through a processor node 120a-b that is local to the cache unit.

In certain embodiments that include one or more non-volatile storage devices 125a-b comprising a plurality of non-volatile storage volumes 130a-n, 132a-n, each cache unit for the non-volatile storage volumes 130a-n, 132a-n may be located on a memory 112 unit local to one or more of the processor nodes 120a-b (e.g., RAM or other host memory), a flash device local to one or more of the processor nodes 120a-b (e.g., a flash cache), or the like. In such an embodiment, the storage access module 160 may use an ALUA protocol to group ports 122 that are local to the processor nodes 120a-b associated with the memory 112 unit or flash device and may notify a processor node 120a-b, a storage client 116 of the ports 122, or the like which port 122 or ports 122 may provide the most efficient or optimized access path for the cache unit. In such an embodiment, a processor node 120a-b assigned to the cache unit may comprise the processor node 120a-b that is nearest to or most local to the non-volatile storage device 125a-b (e.g., the backing store), which may provide an optimal path when populating or flushing the cache unit, for example. In a further embodiment, the processor node 120a-b assigned to the cache unit may be an arbitrary processor node 120a-b, for example, where data is retrieved from the cache unit without accessing the non-volatile storage device 125a-b. In this manner, the storage access module 160, in certain embodiments, may use an ALUA protocol to optimize cache access for NUMA nodes or other processor nodes 120a-b.

In one embodiment, the storage access module 160 may comprise executable software code, such as a device driver, or the like, stored on the computer readable storage media 114 for execution on the processors of the processor nodes 120a-b. In another embodiment the storage access module 160 may comprise logic hardware of one or more of the non-volatile memory devices 125a-b, such as a non-volatile memory media controller, a non-volatile memory controller, a device controller, a field-programmable gate array (FPGA) or other programmable logic, firmware for an FPGA or other programmable logic, microcode for execution on a microcontroller, an application-specific integrated circuit (ASIC), or the like. In a further embodiment, the storage access module 160 may include a combination of both executable software code and logic hardware.

The computing device 110 may also include a communications adapter 135. The communications adapter 135 may include a host bus adapter that includes, but is not limited to: a SCSI host adapter, a Fibre Channel interface card, an InfiniBand interface card, an ATA host adapter, a serial attached SCSI (SAS) host adapter, a SATA host adapter, an eSATA host adapter, and/or the like. Even though only one communications adapter 135 is depicted in FIG. 1, the computing device 110 may include a plurality of communications adapters 135.

The communications adapter 135, in certain embodiments, includes ports 122 associated with non-volatile storage volumes 130a-n, 132a-n of the non-volatile storage devices 125a-b. Thus, a storage client 116 on the storage network 115, in order to access a non-volatile storage volume 130a-n, 132a-n, may specify a port 122 associated with the non-volatile storage volume 130a-n, 132a-n. In certain embodiments, a storage client 116 on the storage network 115 may specify a port 122 associated with the communications adapter 135 based on an ALUA port grouping, without specifying a port 122 associated with a processor node 120a-b, a port 122 associated with a non-volatile storage volume 130a-n, or the like. In such an embodiment, an operating system, hardware connectivity, internal software, or the like (e.g., controller, driver, firmware) may select the ports 122 associated with the processor nodes 120a-b, the ports associated with the non-volatile storage volumes 130a-n, or the like, that may be used to access the non-volatile storage volumes 130a-n. The communications adapter 135 may be in communication with one or more processor nodes 120a-b over a bus 140, which may be substantially similar to the other busses 145, 150 included in the computing device 110. The communications adapter 135 may comprise one or more network interfaces configured to communicatively couple the computing device 110 to a storage network 115 and/or to one or more remote, network-accessible storage clients 116.

In certain embodiments, the computing device 110 may be configured to provide storage services to one or more storage clients 116. The storage clients 116 may include local storage clients 116 operating on the computing device 110 and/or remote storage clients 116 accessible via the storage network 115 (and communications adapter 135). The storage clients 116 may include, but are not limited to: operating systems, file systems, database applications, server applications, kernel-level processes, user-level processes, applications, and the like.

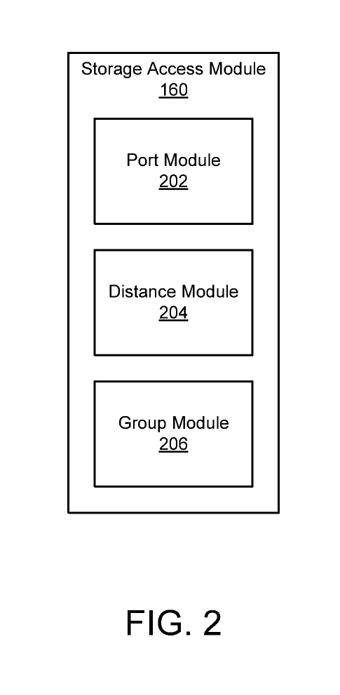

FIG. 2 depicts one embodiment of a storage access module 160. The storage access module 160 may be substantially similar to the storage access module 160 described above with regard to FIG. 1. In one embodiment, as described above, the storage access module 160 determines a plurality of ports 122 through which a non-volatile storage volume 130a-n, 132a-n is accessible, determines distances between a processor node 120a-b and the ports 122, and assigns the ports 122 to a plurality of groups based on the determined distances. In the depicted embodiment, the storage access module 160 includes a port module 202, a distance module 204, and a group module 206, which are described in more detail below. In certain embodiments, the port module 202, the distance module 204, and/or the group module 206 are located on a target system (e.g., the system that contains the one or more processor nodes 120a-b, the non-volatile storage devices 125a-b, the non-volatile storage volumes 130a-n, 132a-n, and/or the communications adapter 135).

The port module 202, in one embodiment, is configured to determine and/or discover a plurality of ports 122 through which a non-volatile storage volume 130a-n, 132a-n or other memory and/or storage is accessible. As described above, in certain embodiments, the non-volatile storage volumes 130a-n, 132a-n are exported and/or accessible through a plurality of ports 122, such as ports 122 of the processor nodes 120a-b, the non-volatile storage devices 125a-b, the communications adapter 135, and/or the like.

In one embodiment, the port module 202 determines whether ports 122 are local or remote to a particular processor node 120a-b. As used herein, local ports 122 may be ports 122 that are directly connected to, or accessible to, a processor node 120a-b (and/or the processors within the processor node 120a-b), without accessing a different processor node 120a-b over an interconnect bus 150 or the like. Remote ports 122 may be ports 122 that are not directly connected to a processor node 120a-b, but are directly connected to, and accessible through, a different processor node 120a-b. For example, ports 122 that connect the processor node 120a to the non-volatile storage device 125a are local to the processor node 120a, but remote to the processor node 120b, even though the ports 122 may all be part of the same computing device 110 and are local to the computing device 110.

The port module 202, in some embodiments, maintains a list of available ports 122 for each processor node 120a-b, each non-volatile storage device 125a-b, each non-volatile storage volume 130a-n, 132a-n, or at another granularity. In certain embodiments, the port module 202 updates, adds to, or removes from, a list of available ports 122 in response to a port 122 being added, removed, modified, or the like. In some embodiments, the port module 202 refreshes a list of ports 122 periodically at predetermined time periods. For example, the port module 202 may scan the computing device 110 and refresh the list of ports 122 once an hour or at another predefined interval; in response to a trigger such as a storage request, memory access, and/or the computing device 110 powering on; or the like. In certain embodiments, the port module 202 maintains port 122 information in a configuration file. In a further embodiment, the port module 202 maintains port 122 information in volatile memory 112. In a further embodiment, the port module 202 may create or update a list of ports 122 in response to a storage request and/or memory access for a non-volatile storage volume 130a-n, 132a-n.

In one embodiment, the distance module 204 is configured to determine or otherwise reference one or more distances between a processor node 120a-b and one or more ports 122 through which a non-volatile storage device 125a-b, a non-volatile storage volume 130a-n, 132a-n, a volatile memory 112, or the like is accessible. As used herein, a distance may comprise a statistic, measurement, metric, identifier, indicator, and/or representation associated with a speed, latency, travel time, length, for data between two points. A distance may include a number of hops, a bandwidth, a latency, whether the two points are local or remote, or the like. In another embodiment, a distance may be a relative distance value, a ratio, or the like. For example, the determined distance for the processor node 120b to access data stored in the non-volatile storage volume 130a may comprise two hops, because the non-volatile storage volume 130a is remote to the processor node 120b and local to the processor node 120a. In such an embodiment, the non-volatile storage volume 130a is accessible using one or more ports 122 that are local to processor node 120a and remote to processor node 120b. The processor node 120b, in certain embodiments, communicates through the processor interconnect 145 to request the data from the processor node 120a having ports 122 local to the non-volatile storage volume 130a.

In one embodiment, the distance module 204 may determine and/or reference a distance as a distance between processor nodes 120a-b. For example, the distance module 204, in one embodiment, uses a NUMA distance between NUMA nodes 120a, 120b as the distance. In certain embodiments, the distance module 204 references and/or receives distances from a BIOS for the computing device 110. For example, in one embodiment, the BIOS defines distances between processor nodes 120a-b. In one embodiment, the distance module 204 references and/or receives a distance from the BIOS in response to providing a command to the BIOS, such as a “numactl” NUMA utility or the like. In some embodiments, the distance module 204, the command (e.g., the “numactl” NUMA utility), or the like receives distance information from the operating system. Thus, the BIOS may contain the definitions describing a distance, which are read by the operating system, and the operating system may present the distance definition information to the distance module 204 or another interested component, such as a processor node 120a-b, a storage controller, or the like. In another embodiment, the distance module 204 determines distances based on whether ports 122 are local or remote to a processor node 120a-b. For example, the distance module 204 may determine that local ports 122 have a distance of ‘1’ and remote ports 122 have a distance of ‘2’. In certain embodiments, the BIOS determines whether ports 122 are local or remote for a particular processor node 120a-b, which may be requested by the distance module 204 using “numactl.”

In another embodiment, the distance module 204 references or retrieves distances from a configuration file or set of configuration files, an endpoint provided by an operating system, a database, or another data structure. In one embodiment, the distance module 204 references or retrieves distances from a predefined table of distance information based on the system type, e.g., based on the system architecture. In certain embodiments, the BIOS, kernel, operating system, processor nodes 120a-b, controllers, or the like, may store distances in a configuration file or other data structure, which the distance module 204 may subsequently reference or read to determine the distances. In another embodiment, the distance module 204 determines a distance by receiving the distance from a user, during configuration of a storage volume 130a-n, 132a-n, or the like. In some embodiments, a user may store distances in a configuration file or other data structure, which the distance module 204 may read from the configuration file to determine the distances.

In certain embodiments, a plurality of processor nodes 120a-b may be considered local to a non-volatile storage device 125a-b, or vice versa. For example, on some Intel® architectures, there may be two or more processor nodes 120a-b that are considered local to a non-volatile storage device 125a-b. In such an embodiment, the BIOS may only report one of the plurality of local processor nodes 120a-b to the distance module 204 as being local, may report several of the local processor nodes 120a-b to the distance module 204 as being local, or the like. In embodiments where less than all of the local processor nodes 120a-b are reported, the distance module 204 may determine one or more distances itself; may make an educated guess to determine the unreported local processor nodes 120a-b based on various factors such as information maintained by the BIOS or the kernel, the system architecture, the system performance, or the like; may use a default distance for the unreported local processor nodes 120a-n; may consider the unreported local processor nodes 120a-n as remote; or the like.

The group module 206, in one embodiment, is configured to assign one or more ports 122 to a plurality of groups based on the distances determined by the distance module 204. In some embodiments, the group module 206 determines a group designation for a port and assigns the port to the designated port group. In certain embodiments, the group module 206 assigns the ports 122 to groups to facilitate the efficient transfer of data to/from the non-volatile storage volumes 130a-n, 132a-n, so that the processor nodes 120a-b prioritize ports 122 with shorter distances (e.g., a preferred group) and use other ports 122 with longer distances as failover, fallback, or backup access. For example, in one embodiment, one or more of the non-volatile storage volumes 130a-n of the non-volatile storage device 125a are exported and accessible on ports 122 of both the processor node 120a and the processor node 120b, even though the non-volatile storage device 125a and associated storage volumes 130a-n are local to the processor node 120a. Thus, some ports 122 associated with a particular non-volatile storage volume 130a-n, 132a-n may be more optimal or efficient than other ports 122 in terms of the distance, number of hops, latency, or bandwidth required to access the non-volatile storage volume 130a-n, 132a-n through the ports 122. In one embodiment, the group module 206 assigns the efficient ports 122 for a non-volatile storage volume 130a-n, 132a-n (e.g., ports 122 with a lower distance) to a different port group than the less efficient ports 122 (e.g., ports 122 with a higher distance).

In one embodiment, the group module 206 determines different port groups for each non-volatile storage volume 130a-n, 132a-n and/or for each processor node 120a-b. For example, the ports 122 comprising a preferred port group for the non-volatile storage volume 130a may be different than the ports 122 comprising a preferred port group for the non-volatile storage volume 132a. In one embodiment, the group module 206 assigns the ports 122 to groups for each processor node 120a-b. For example, the ports 122 comprising a preferred port group for the processor node 120a may be different than the ports 122 comprising a preferred port group for the processor node 120b. In this manner, in certain embodiments, the group module 206 may determine at least two port groups for each storage volume 130a-n, 132a-n that are accessible to a processor node 120a-b, for each processor node 120a-b.

In one embodiment, in a computing device 110 that implements a NUMA architecture, by default the ports 122 may be grouped into a single group. An initiator may select a port 122 to access a non-volatile storage volume 130a-n, 132a-n based on different port selection methods. For example, the initiator may use a round-robin method to select a port 122 such that commands are sent to ports 122 in a circular order. In another example, the initiator may use a least queue depth method that tracks the number of commands that are outstanding for a port 122 and selects a port 122 according to the least amount of outstanding commands, a most recently used method that continues to use the last port 122 through which a storage volume 130a-n, 132a-n was successfully accessed, or the like. These default access methods, in certain embodiments, do not consider distance or prioritize ports based on distance.

Instead of or in addition to using a default access method, in one embodiment, the group module 206 assigns ports 122 to groups based on distance using an asymmetric logical unit access (ALUA) protocol or another asymmetric access protocol. As used herein, ALUA is an asymmetric access, multipathing protocol, usually within a SCSI framework, that provides access state and path attribute management for ports 122. In certain embodiments, the access states and/or path attributes comprise usage priorities with which a processor node 120a-b uses or accesses the ports 122, as described above. In some embodiments, the storage access module 160 (e.g., using the selection module 302 described below) uses the ALUA protocol to determine which path to use to access the data of a non-volatile storage volume 130a-n, 132a-n (e.g., which ports 122, processor nodes 120a-b, and non-volatile storage devices 125a-b are accessed to reach the data). ALUA, in certain embodiments, comprises two path-determining forms: an explicit form, where the path is determined by a target, and an implicit form, where the path is determined by an initiator.

Using ALUA or another asymmetric access protocol, for example, the group module 206 may assign SCSI ports 122 (e.g., SCSI initiator or target ports 122) to two groups based on the distances determined by the distance module 204: a preferred group and a non-preferred group, or the like. A preferred group, as determined by the group module 206, may include ports 122 that are local to a processor node 120a-b, local to a non-volatile storage volume 130a-n, 132a-n, or the like and a non-preferred group may include ports 122 that are remote to the processor node 120a-b, remote to the non-volatile storage volume 130a-n, 132a-n, or the like. The group module 206, in certain embodiments sets or unsets an indicator, such as a “preferred” bit, for a port 122, using the ALUA protocol or the like. In one embodiment, the preferred bit or other indicator is set (e.g., set to “True,” ‘1,’ “On” or the like) if a port 122 is a preferred port 122 and is unset (e.g., set to “False,” ‘0,’ “Off,” or the like) if a port 122 is not a preferred port 122. The group module 206, in one embodiment, may set a preferred bit or other priority indicator for a port 122 in a configuration file or other data structure using the ALUA protocol or the like. In a further embodiment, the group module 206 may set a preferred bit or other priority indicator for a port 122 using a command of the ALUA protocol or the like.

In a NUMA architecture, the group module 206, in certain embodiments, may use ALUA or another protocol to assign ports 122 to groups based on the determined distances described above with regard to the distance module 204 (e.g., a distance between ports 122 local to a processor node 120a-b and ports 122 local to a non-volatile storage volume 130a-n, 132a-n, a distance between processor nodes 120a-b, a distance between a processor node 120a and a non-volatile storage device 125a-b, or the like). Using ALUA to group the ports 122 into different usage priorities for different NUMA nodes 120a-b, even though the NUMA nodes 120a-b are part of the same computing device 110, in certain embodiments, may increase access speed, increase available bandwidth, decrease latency, or the like when compared to default access methods for NUMA nodes 120a-b and/or for default access methods for ALUA, which may only apply over a storage network 115, or the like, not for processor nodes 120a-b and storage devices 125a-b within a single computing device 110.

As described above, local ports 122 or paths of a processor node 120a-b are ports 122 that are part of, integrated with, or associated with the processor node 120a-b, providing a direct path to the non-volatile storage volume 130a-n, 132a-n. Remote ports 122 or paths, on the other hand, are ports 122 providing an indirect path to the non-volatile storage volume 130a-n, 132a-n, such as the ports 122 associated with a different processor node 120a-b or the like. For example, the non-volatile storage volumes 130a-n are local to the processor node 120a, but remote to the processor node 120b, even though they may be accessed by either of the processor nodes 120a-b. In some embodiments, the group module 206 assigns ports 122 having a distance below a predetermined threshold to a preferred group and ports 122 having a distance above the predetermined threshold to a non-preferred group, may assign ports to three or more different groups, or the like, based on distance values.

In another embodiment, one or more of the non-volatile storage volumes 130a-n, 132a-n may comprise a volume that spans a plurality of non-volatile storage devices 125a-b, for example, a non-volatile storage volume 130a-n, 132a-n that implements data striping, a non-volatile storage volume 130a-n, 132a-n in a RAID configuration, or the like. The non-volatile storage devices 125a-b comprising a RAID volume, for example, may be local to different processor nodes 120a-b. Consequently, ports 122 associated with the RAID volume may be local to a plurality of processor nodes 120a-b. In one embodiment, the group module 206 may determine which processor nodes 120a-b are local to the non-volatile storage devices 125a-b comprising the RAID volume and group the ports 122 for the processor nodes 120a-b into an active/optimized, preferred port group. Alternatively, in one embodiment, the group module 206 may notify an initiator device (e.g., a storage client 116) to segment access requests for the RAID volume and to send the different segments to different ports 122.

For example, in certain embodiments, the group module 206 may specify that requests to addresses 0-32k of the RAID volume be sent to ports 122 in port group A, which may be local to the processor node 120a, and requests to addresses 32k-64k of the RAID volume be sent to the ports 122 in port group B, which may be local to the processor node 120b. In this manner, the active/optimized, preferred ports 122, in one embodiment, may be efficiently utilized instead of sending all requests to a single processor node 120a-b, which may be local to a non-volatile storage device 125a-b for only a portion of the requests or the like. The other portion of the requests, in one embodiment, may go through or use a different (e.g., remote) processor node 120a-b to reach a non-volatile storage device 125a-b that fulfills the request.

In another embodiment, the group module 206 assigns a state setting to the ports 122. The state setting may comprise a state bit or other indicator for a port 122 that is set or unset by the group module 206, a command for a port 122, a setting in a configuration file or other data structure for a port 122, or the like. As described above, the same port 122 may have different settings for different processor nodes 120a-b, different storage volumes 130a-n, 132a-n, or the like. For example, a port 122 may be associated with a state bit or other setting (e.g., for each processor node 120a-b and/or each storage volume 130a-n, 132a-n) that comprises multiple states or priorities.

For example, in an embodiment where the group module 206 uses ALUA to group the ports 122, the group module 206 may use one or more ALUA states, including but not limited to, in order of priority, an “active/optimized” state, an “active/non-optimized” state, a “standby” state, an “unavailable” state, or the like to assign the ports 122 to different groups with different usage priorities. Active state ports 122 may include one or more ports 122 that are available to access non-volatile storage volumes 130a-n, 132a-n, the ports 122 in an unavailable state may include one or more ports 122 that have failed or are not currently available, and the ports 122 in a standby state may include one or more ports 122 that were unavailable, but have come back online or the like. Within the active state ports 122, in one embodiment, the group module 206 associates or groups one or more local ports 122 as optimized ports 122 (e.g., an “active/optimized” state) and associates or groups one or more remote ports 122 as non-optimized ports 122 (e.g., an “active/non-optimized” state) based on distances from the distance module 204. In a further embodiment, the group module 206 may determine three or more groups of ports 122 for a certain storage volume 130a-n, 132a-n and processor node 120a-b based on multiple distance thresholds or the like, such as an “active/optimized” port group, an “active/non-optimized” port group, a “standby” port group, or the like.

As described above, the group module 206, in a further embodiment, instead of or in addition to grouping the ports 122 by state (e.g., ALUA states), may set a preferred bit or other indicator for one or more ports 122. Depending on the implementation of ALUA, in various embodiments, the preferred bit may override one or more ALUA state designations, one or more ALUA state designations may override a preferred bit, or the like. For example, in one embodiment, a preferred bit may be ignored for one or more ports 122 in an “active/optimized” state. In certain embodiments, the group module 206 assigns the ports 122 to two groups based on the preferred bit and the port state: an active/optimized, preferred port group and an active/non-optimized, non-preferred group, or the like. In a further embodiment, the group module 206 may use the preferred bit and the port state to assign the ports 122 to more than two groups, such as one or more of an active/optimized, preferred port group; an active/optimized, non-preferred port group; an active/non-optimized, preferred port group; an active/non-optimized non-preferred port group; a standby preferred port group; a standby non-preferred port group; or the like. A usage priority of various groups with different preferred bit and port state combinations may be based on an ALUA version and/or implementation and the group module 206 may determine a preferred bit setting and a port state for different port groups based on the usage priorities and the distances, so that shorter distances have higher usage priorities, or the like. A device may determine, based on the groups created by the group module 206, which ports 122 to use to access the non-volatile storage volumes 130a-n, 132a-n.

The standby port state, in one embodiment, may indicate that a port 122 may become available if needed (e.g., if the bandwidth on other ports 122 or port groups becomes too high or the like). In certain embodiments, a high availability (HA) system (e.g. a cluster) may be provided that comprises a plurality of connected computing devices 110, processor nodes 120a-b, storage controllers, or the like, with each computing device 110 storing the same data to provide redundancy. In such an embodiment, the group module 206 may group ports 122 (e.g., by using ALUA or a similar access protocol) from each computing device 110 in the HA system. Thus, because each computing device 110 stores the same data, one computing device 110 may be actively used while the other is in a standby mode and is only activated when the active computing device 110 is not able to fulfill data transactions (e.g., read/write operations). Consequently, the group module 206 may assign the ports 122 of the non-active computing device 110 a “standby” state. Thus, ports 122 of the non-active computing device 110 may be grouped into a standby, preferred group and a standby, non-preferred group, which, when activated (e.g., when the port groups become available), may be modified to an active/optimized, preferred group and a non-active/non-optimized, non-preferred group, or the like.

In certain embodiments, the group module 206 maintains a list or other record of port groups associated with each non-volatile storage volume 130a-n, 132a-n for each processor node 120a-b. In one embodiment, a driver on the computing device 110 maintains the list of port groups in a configuration file, or the like. In another embodiment, the group module 206 detects modifications associated with one or more ports 122 within the computing device 110 and updates the list of port groups accordingly. For example, the group module 206 may recreate the port groups and update the list of port groups in response to detecting a port 122 being added or removed (e.g., becoming available or unavailable). In another embodiment, the group module 206 detects one or more storage clients 116 and sends an updated list of port groups to the storage clients 116 in response to the modifications to the port groups. In certain embodiments, the group module 206 generates port groups dynamically in real-time, during runtime, or the like. In a further embodiment, the group module 206 may generate port groups during configuration of a storage volume 130a-n, 132a-n, at startup of the computing device 110, or the like.

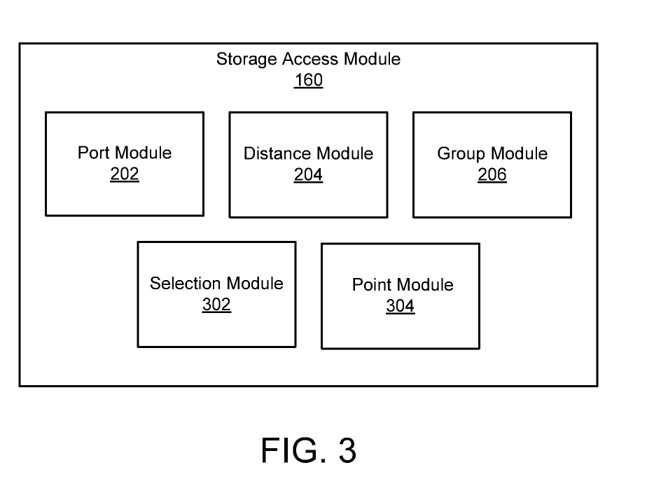

FIG. 3 depicts another embodiment of a storage access module 160. The storage access module 160 may be substantially similar to the storage access module 160 described above with regard to FIGS. 1 and 2. In the depicted embodiment, the storage access module 160 includes a port module 202, a distance module 204, and group module 206, which may be substantially similar to the port module 202, the distance module 204, and the group module 206 described above with reference to FIG. 2. In another embodiment, the storage access module 160 includes a selection module 302 and a point module 304, which are described in more detail below.

In certain embodiments, the selection module 302 and/or the point module 304 may be located on an initiator system, such as a storage client 116 on the storage network 115. Other modules, such as the port module 202, the distance module 204, and/or the group module 206, in certain embodiments, may be located on a target system, such as the computing device 110 described above. In a further embodiment, the selection module 302 and/or the point module 304 may be located on a target system.

The selection module 302, in certain embodiments, selects a port group of a plurality of port groups and/or a port 122 of the selected port group to use for data access. The selection module 302, in certain embodiments, selects a port group based on the port group and/or path settings, such as the preferred bit, port states, usage priorities, or other settings described above. For example, the selection module 302 may select a preferred group before a non-preferred group, an active/optimized group before an active/non-optimized group, or the like. In response to selecting an active/optimized, preferred group, or the like, the selection module 302 may determine a port 122 to use from within the selected group. The selection module 122 may select a port 122 based on the command queue associated with each port 122 (e.g., how many commands each port 122 has to process). Alternatively, the selection module 122 may select a port using a round-robin selection method where ports 122 are selected in a circular order. In another embodiment, the selection module 122 selects a port 122 based on a determined distance associated with the port 122. For example, if a port group comprises ports 122 having a distance below or above a predetermined threshold, the selection module 302 may select a port 122 having the lowest distance. In certain embodiments, the selection module 302 selects a port group automatically based on a previous selection, a configuration file, a port group selection history, or the like instead of selecting a port group each time a non-volatile storage volume 130a, 132a is accessed.

In another embodiment, the selection module 302 selects a port group with a lower usage priority (e.g., an active/non-optimized and/or non-preferred port group) in response to one or more ports 122 of a port group with a higher usage priority (e.g., an active/optimized and/or preferred port group) being unavailable. A port group may be unavailable in response to a hardware failure (e.g., a communications adapter 135 failure; a bus 140, 145, 150 failure; a controller failure; a power failure; a connection failure; or the like). In certain embodiments, a port group may be unavailable if the ports 122 within the group are processing a large number of commands and if it would be more efficient to select a port 122 from the non-active/non-optimized, non-preferred port group. For example, a port group may be unavailable if one or more ports of the port group perform outside of a predetermined threshold or otherwise fail to satisfy a predetermined threshold, such as a latency threshold, a bandwidth threshold, or the like. In one embodiment, if a port group performs below a predetermined threshold in terms of bandwidth, latency, or the like, the selection module 302 may consider the port group to be unavailable and select a different port group. The selection module 302, in certain embodiments, may determine a usage priority or order in which to use different port groups based on scores for the port groups from the point module 304.

In one embodiment, the point module 304 assigns a score or point value to each group of ports 122 determined by the group module 206. In an embodiment using ALUA, for example, the point module 304 may assign points or another score based on the access states, preferred bits, and/or path attributes of the port group. For example, the group module 206 may assign a port group eighty points for being a preferred port 122, fifty points for being in an active/optimized state, ten points for being in an active/non-optimized state, and one point for being in a standby state, or the like, thereby using various weights or priorities for one or more port settings or indicators to determine an ordered list of port groups by usage priority. In the example embodiment, an active/optimized, preferred port group (e.g., a local port group) may have a score of one hundred and thirty and an active/non-optimized, non-preferred port group (e.g., a remote port group) may have a score of ten.

In certain embodiments, the selection module 302 may select a particular port group in response to the port group having a higher score (e.g., more points) than a different port group, or the like. In one embodiment, the point module 304 may use default usage priorities of the ALUA protocol or another asymmetrical access protocol to determine points or a score for different port groups.

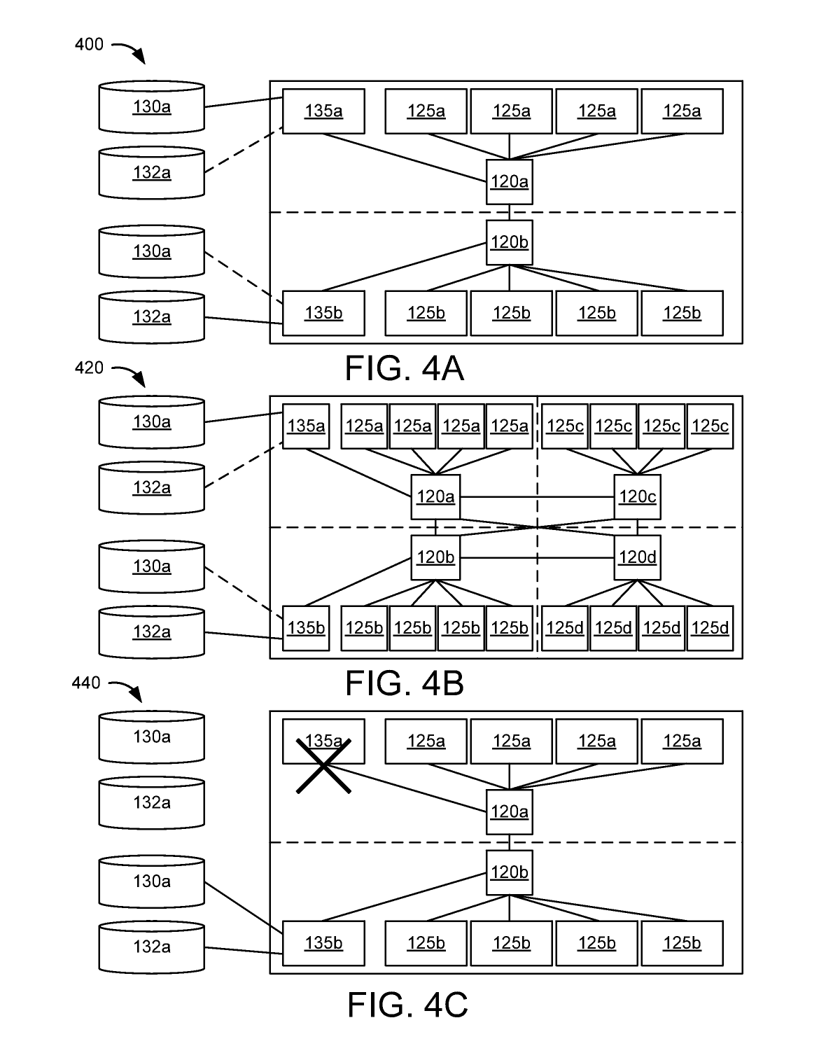

FIG. 4A depicts one embodiment of a system 400 for grouping storage ports 122 based on distances. In one embodiment, FIG. 4A depicts a processor node 120a-b with its associated non-volatile storage devices 125a-b and communications adapters 135a-b. As depicted, the non-volatile storage volume 130a associated with the processor node 120a and the non-volatile storage volume 132a associated with the processor node 120b are accessible by the storage clients 116 via the communications adapters 135a-b. In certain embodiments, the processor nodes 120a-b may comprise NUMA processor nodes 120a-b.

In one embodiment, the non-volatile storage volume 130a is local to the processor node 120a and the non-volatile storage volume 132a is local to the processor node 120b. For each of the non-volatile storage volumes 130a, 132a and each of the processor nodes 120a-b, the port module 202 may determine the ports 122 through which the non-volatile storage volumes 130a, 132a may be accessed. For example, the non-volatile storage volume 130a may be accessible locally to the processor node 120a using one or more local ports 122 of the processor node 120a (e.g., local ports 122 in communication with one of the non-volatile storage devices 125a, the communications adapter 135a, or the like) and accessible remotely to the processor node 120a using one or more ports 122 of the processor node 120b (e.g., remote ports 122 in communication with the communications adapter 135b, or the like). The port module 202 may determine a similar arrangement of available ports 122 for the non-volatile storage volume 132a and the processor node 102b.

In some embodiments, the distance module 204 determines distances between the ports 122 that are local to a processor node 120a-b and the ports 122 that are local to a non-volatile storage volume 130a, 132a, distances between processor nodes 120a-b, or the like. Thus, for example, if the non-volatile storage volume 130a of the non-volatile storage device 125a is the target volume, the ports 122 that are local to the processor node 120a may have lower distances than the ports 122 that are local to the processor node 120b because the non-volatile storage volume 130a is local to the processor node 120a.

The group module 206, in one embodiment, groups the local ports 122 into an active, optimized, and/or preferred group for a particular non-volatile storage volume 130a, 132a and groups the remote ports 122 into a non-optimized, non-preferred, and/or standby group. In certain embodiments, the group module 206 uses an ALUA protocol to assign the ports 122 to various groups and to notify device drivers, processor nodes 120a-b, storage clients 116, or the like of the port groups. Thus, a storage client 116, for example, accessing the non-volatile storage volume 132a through the processor node 120b may access the data using a port 122 in an active, optimized, and/or preferred port group associated with the processor node 120b and the non-volatile storage volume 132a. In the depicted embodiment, the data access path may be directly from a non-volatile storage device 125b to the processor node 120b, from the communications adapter 135b to the processor node 120b, or the like. In some embodiments, a storage client 116 on the storage network 115 specifies a port 122 associated with the communications adapter 135 based on an ALUA port grouping. In such an embodiment, the storage client 116 may not specify any internal components, such as the processor nodes 120a, 120b, one or more ports 122 associated with the processor nodes 120a, 120b, one or more ports 122 associated with the non-volatile storage volumes 130a, 132a, or the like to access the non-volatile storage volumes 130a, 132a. Instead, the selection module 302 may select the internal components based on an operating system, hardware connectivity, internal software, or the like (e.g., storage controllers, drivers, firmware).

In certain embodiments, the non-volatile storage volumes 130a, 132a are accessible over each communications adapter 135a-b, to each processor node 120a-b, or the like; however, for each non-volatile storage volume 130a, 132a, one access path may be more efficient than another. For example, accessing a non-volatile storage volume 130a, 132a associated with a non-volatile storage device 125b through the communications adapter 135b will be more efficient than accessing the same non-volatile storage volume 130a, 132a using the communications adapter 135a because accessing the non-volatile storage volume 130a, 132a associated with a non-volatile storage device 125b through the communications adapter 135a may require an extra hop (e.g., a greater distance) to go through processor node 120a and processor interconnect 145. In certain embodiments, if the active, preferred port group associated with non-volatile storage volume 132a is not available, the access path may follow the communications adapter 135a to processor node 120a and then to processor node 120b and then to a non-volatile storage device 125b associated with the non-volatile storage volume 132a. Thus, the non-optimized and/or non-preferred port group may include the ports 122 on an access path that is longer (e.g., has a greater distance) than an access path associated with the ports 122 of an active, optimized, and/or preferred port group.

FIG. 4B depicts one embodiment of another system 420 for grouping storage ports 122 based on distances. The system 420 includes a plurality of processor nodes 120a-d, a plurality of non-volatile storage devices 125a-d, a plurality of communications adapters 135a-b, and a plurality of non-volatile storage volumes 130a, 132a, which may be substantially similar to the processor nodes 120a-b, the non-volatile storage devices 125a-b, the communications adapters 135a-b, and/or the non-volatile storage volumes 130a, 132a of FIG. 4A.

In certain embodiments, the processor nodes 120c-d are not directly connected to a communications adapter 135a-b. Thus, the path to access a non-volatile storage volume 130a, 132a associated with the non-volatile storage devices 125c-d, may include multiple hops through the processor nodes 120a-d. For example, to access a non-volatile storage volume 132a located on the non-volatile storage devices 125d, the access path may traverse a communications adapter 135b, a processor node 120b, another processor node 120d, and one or more of the non-volatile storage devices 125d. Because the processor nodes 120a-d may be connected using a processor interconnect 145, such as QPI, the access path to a non-volatile storage volume 130a, 132a located on the non-volatile storage devices 125c-d may cross the processor node 120a, the processor node 120b, or both.

In certain embodiments, the storage access module 160 may use the ALUA protocol to determine the optimal ports 122 for an access path to a non-volatile storage volume 130a, 132a, even though the storage devices 125a-d, the processor nodes 120a-d, and the communications adapters 135a-b may all be part of and/or local to a single computing device 110. In one embodiment, the processor nodes 120a-d may comprise NUMA nodes 120a-d and the storage access module 160 may use ALUA to assign the ports 122 to different groups based on a distance (e.g., a NUMA distance) between the ports 122 on the NUMA nodes 120a-d remote to a non-volatile storage volume 130a, 132a and the ports 122 on NUMA nodes 120a-d local to the non-volatile storage volume 130a, 132a. For example, for a non-volatile storage volume 130, 132a associated with the NUMA node 120d, the ports 122 located on the NUMA node 120d may be local to the non-volatile storage volume 130a, 132a and the ports 122 located on the NUMA nodes 120a-c may be remote to the non-volatile storage volume 130a, 132a. The distance module 204 may determine the distances between the remote ports 122 and the local ports 122 and, based on the determined distances, the group module 206 may use ALUA to group the ports 122 into different groups. A storage client 116 may use the determined port groups to access the non-volatile storage volume 130a, 132a using ports 122 associated with a most efficient available path, or the like. In some embodiments, a storage client 116 on the storage network 115 may specify a port 122 associated with the communications adapter 135 based on an ALUA port grouping, without specifying any internal components, such as the processor nodes 120a-d, one or more ports 122 associated with the processor nodes 120a-d, one or more ports 122 associated with the non-volatile storage volumes 130a, 132a, or the like to access the non-volatile storage volumes 130a, 132a. Instead, the selection module 302 may select the internal components or paths based on an operating system, hardware connectivity, internal software, or the like (e.g., a storage controller, driver, firmware).

FIG. 4C depicts one embodiment of a system 440 for grouping storage ports 122 based on distances. The system 440 includes a plurality of processor nodes 120a-b, a plurality of non-volatile storage devices 125a-b, a plurality of communications adapters 135a-b, and a plurality of non-volatile storage volumes 130a, 132a, which may be substantially similar to the processor nodes 120a-b, the non-volatile storage devices 125a-b, the communications adapters 135a-b, and the non-volatile storage volumes 130a, 132a of FIGS. 4A and/or 4B.

Unlike FIG. 4A, FIG. 4C depicts a system 440 where a communications adapter 135a is unavailable. In the depicted embodiment, a storage client 116 may not be able to access a non-volatile storage volume 130a, 132a associated with the processor node 120a through the unavailable communications adapter 135a and the associated port 122 of the processor node 120a. The storage client 116 may, however, continue to access the non-volatile storage volume 130a, 132a associated with the processor node 120a using the communications adapter 135b and a processor interconnect 145 between processor node 120a and 120b, or the like.

In certain embodiments, in response to the communications adapter 135a being unavailable, the storage access module 160 may use a different port group to access the non-volatile storage volume 130a, 132a. For example, the storage access module 160 may select one or more ports 122 of a non-optimized, non-preferred, and/or standby port group instead of ports of an active, optimized, and/or preferred port group which may be unavailable due to the unavailability of the communications adapter 135a. In one embodiment, the port module 202 may detect that the communications adapter 135a is unavailable and the group module 206 may regroup the ports 122 for a non-volatile storage volume 130a, 132a. Thus, one or more ports 122 that may have been in a non-optimized, non-preferred, and/or standby port group before the communications adapter 135a became unavailable may be assigned to an active, optimized, and/or preferred port group by the group module 206 in response to the communications adapter 135a being unavailable.

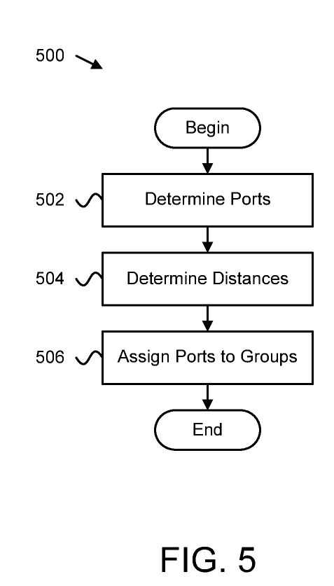

FIG. 5 depicts one embodiment of a method 500 for grouping storage ports 122 based on distances. In one embodiment, the method 500 begins and the port module 202 determines 502 a plurality of ports 122 through which a non-volatile storage volume 130a-n, 132a-n is accessible. In another embodiment, the distance module 204 determines 504 distances between a processor node 120a-b and the ports 122. In a further embodiment, the group module 206 assigns 506 the ports 122 to a plurality of groups based on the determined distances and the method 500 ends. In certain embodiments, the groups may have different usage priorities for the processor node 120a-b.

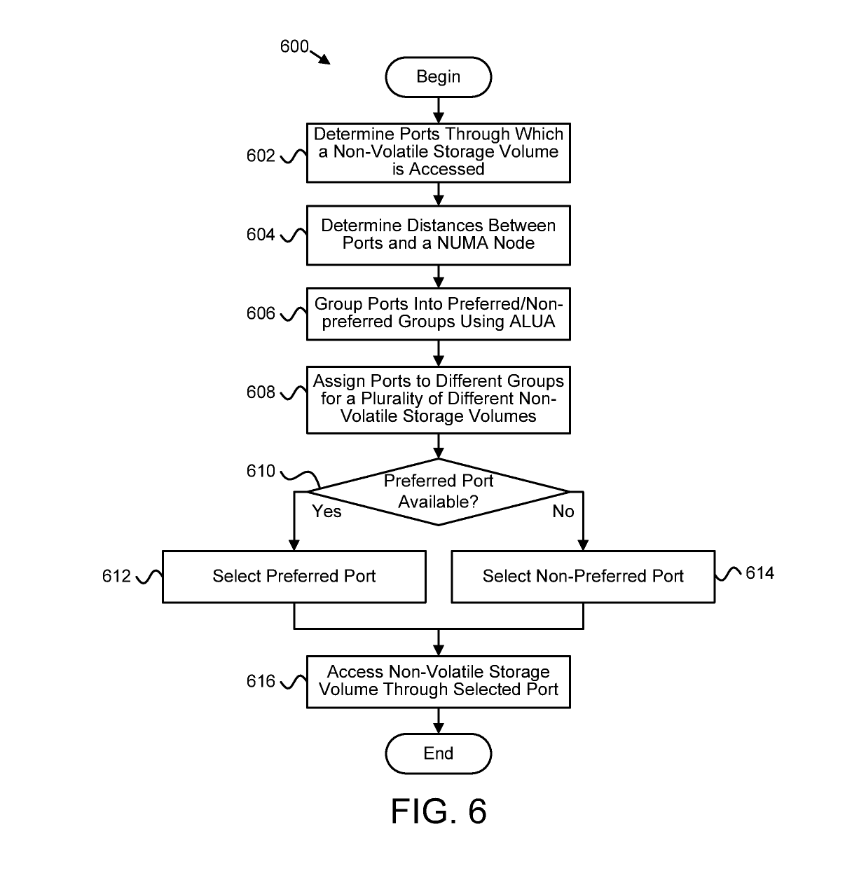

FIG. 6 depicts one embodiment of another method 600 for grouping storage ports 122 based on distances. In one embodiment, the port module 202 determines 602 a plurality of ports 122 through which a non-volatile storage volume 130a-n, 132a-n is accessible. In one embodiment, the port module 202 determines whether the ports 122 are local ports 122 or remote ports 122 for a processor node 120a-b. A processor node 120a-b, in certain embodiments, may comprise a NUMA node 120a-b. In one embodiment, the distance module 204 determines 604 distances between a NUMA node 120a-b and the ports 122. In certain embodiments, the distance may be measured as a number of hops, a latency, a bandwidth, or the like.

In another embodiment, the group module 206 assigns 606 the ports 122 to a plurality of groups based on the determined 604 distances. In another embodiment, the group module 206 assigned ports 122 to a plurality of groups for each non-volatile storage volume 130a-n, 132a-n and/or each NUMA node 120a-b. Thus, in some embodiments, the ports 122 comprising an optimized and/or preferred port group for one non-volatile storage volume 130a-n, 132a-n may be different than the ports 122 comprising an optimized and/or preferred port group for a different non-volatile storage volume 130a-n, 132a-n. In certain embodiments, the group module 206 assigns the ports 122 to groups using an asymmetrical access protocol such as an ALUA protocol or the like.

In another embodiment, the group module 206 assigns 608 the ports 122 to different port groups for each non-volatile storage volume 130a-n, 132a-n. Thus, in one embodiment, each non-volatile storage volume 130a-n, 132a-n may have different ports 122 assigned to different port groups. In some embodiments, the group module 206 assigns the ports 122 to groups with different usage priorities, which may be represented by access states, preferred bits, and/or path attributes associated with the ports 122. In certain embodiments, the group module 206 assigns the ports 122 to at least two groups based on the usage priorities: a preferred group and a non-preferred group, an optimized group and a non-optimized group, or the like.

In one embodiment, the selection module 302 determines 610 whether a port 122 of a preferred port group is available for a non-volatile storage volume 130a-n, 132a-n being accessed by a storage client 116. If the selection module 302 determines 610 that a preferred port 122 is available, the selection module 302 selects 612 the preferred port 122 and a storage client 116 accesses 616 a non-volatile storage volume 130a-n, 132a-n through the selected preferred port 122, and the method 600 ends. If the selection module 302 determines 610 that a preferred port 122 is not available, the selection module 302 selects 614 a port 122 of a non-preferred port group for a non-volatile storage volume 130a-n, 132a-n and a storage client 116 accesses 616 a non-volatile storage volume 130a-n, 132a-n through the selected non-preferred port 122, and the method 600 ends.

A means for determining a number of hops for a plurality of ports 122 and/or paths between a NUMA node 120a-b and a storage medium, in various embodiments, may include a distance module 204, a storage access module 160, a non-volatile memory controller, a non-volatile memory media controller, an SML, other logic hardware, and/or other executable code stored on a computer readable storage medium. Other embodiments may include similar or equivalent means for determining a number of hops.

A means for grouping one or more ports 122 and/or paths for a NUMA node 120a-b based on a determined number of hops, in various embodiments, may include a group module 206, a storage access module 160, a processor, a non-volatile memory controller, a non-volatile memory media controller, an SML, other logic hardware, and/or other executable code stored on a computer readable storage medium. Other embodiments may include similar or equivalent means for grouping one or more ports 122 and/or paths for a NUMA node 120a-b based on a determined number of hops.

A means for accessing a storage medium using one or more ports 122 and/or paths so that a first port group is used before a second port group, in various embodiments, may include a port module 202, a selection module 302, a storage access module 160, a processor, a non-volatile memory controller, a non-volatile memory media controller, an SML, other logic hardware, and/or other executable code stored on a computer readable storage medium. Other embodiments may include similar or equivalent means for accessing a storage medium using one or more ports 122 and/or paths.

A means for detecting that a first port group is unavailable so that a storage medium is accessed using a second port group, in various embodiments, may include a selection module 302, a storage access module 160, a processor, a non-volatile memory controller, a non-volatile memory media controller, an SML, other logic hardware, and/or other executable code stored on a computer readable storage medium. Other embodiments may include similar or equivalent means for detecting that optimized first port group is unavailable.

A means for grouping ports 122 and/or paths into different groups for a different NUMA node 120a-b of the same computing device 110 as another NUMA node 120a-b, in various embodiments, may include a group module 206, a storage access module 160, a processor, a non-volatile memory controller, a non-volatile memory media controller, an SML, other logic hardware, and/or other executable code stored on a computer readable storage medium. Other embodiments may include similar or equivalent means for grouping ports 122 and/or paths into different groups for a different NUMA node 120a-b of the same computing device 110 as another NUMA node 120a-b.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. A method comprising:
determining a plurality of ports through which a non-volatile storage volume is accessible;
determining distances between a processor node and the ports; and
assigning the ports to a plurality of groups based on the determined distances, the groups having different priorities for the processor node.

2. The method of claim 1, wherein the ports are assigned to the plurality of groups using an asymmetric logical unit access (ALUA) preferred bit for the ports.

3. The method of claim 1, wherein determining the distances comprises determining one or more of the ports that are local to the processor node, at least one of the groups comprising the ports that are local.

4. The method of claim 1, wherein the plurality of groups comprise at least a first port group and a second port group based on the determined distances, the first port group comprising ports with lower distances and higher priorities for the processor node than ports of the second port group.

5. The method of claim 4, further comprising selecting a port assigned to the second port group for use by the processor node in response to the ports assigned to the first port group being unavailable.

6. The method of claim 5, wherein the first port group comprises ports that are local to the processor node and the second port group comprises ports that are remote to the processor node.

7. The method of claim 6, wherein the remote ports comprise ports associated with a different processor node of a host device for the processor node.

8. The method of claim 4, wherein the first port group comprises one or more of a preferred port group, an optimized port group, and an active port group and the second port group comprises one or more of a non-preferred port group, a non-optimized port group, and a standby port group, the first and second port groups being defined using an asymmetric logical unit access (ALUA) protocol.

9. The method of claim 1, further comprising determining a plurality of different groups comprising the ports for one or more different non-volatile storage volumes.

10. The method of claim 1, further comprising determining a plurality of different groups comprising the ports for one or more different processor nodes based on distances between the one or more different processor nodes and the ports.

11. The method of claim 1, wherein the processor node comprises one of a plurality of non-uniform memory access (NUMA) nodes of a single computing device.

12. The method of claim 1, wherein the distances comprise one or more of a number of hops, a latency, a bandwidth, whether the port is local, and whether the port is remote.

13. The method of claim 1, wherein at least one port of the plurality of ports comprises a port of a cache for the non-volatile storage volume, the cache being accessible through the at least one port.

14. The method of claim 13, wherein the determined distances comprise a distance between the cache and the at least one port.

15. An apparatus comprising:
a distance module configured to assign distance values to a plurality of ports, the distance values for data communications between a node and the ports, the node comprising one of a plurality of nodes;
a group module configured to assign one or more ports of the plurality of ports to one of a local port group and a remote port group based on the assigned distances; and
a selection module configured to select the remote port group for data communications between the node and a non-volatile storage medium in response to the local port group being unavailable.

16. The apparatus of claim 15, further comprising a point module configured to assign point values to the local port group and the remote port group based on one or more of an access state and a path attribute for the local port group and the remote port group, the selection module configured to select one or more of the local port group and the remote port group for data communications based on the assigned point values.

17. The apparatus of claim 15, further comprising a port module configured to determine that at least a storage volume of the non-volatile storage medium has been exported to the plurality of ports such that the non-volatile storage medium is accessible by the node using the plurality of ports.

18. The apparatus of claim 15, wherein the selection module is configured to determine that the local port group is unavailable in response to the local port group failing to satisfy one or more of a latency threshold and a bandwidth threshold.

19. The apparatus of claim 15, wherein the plurality of nodes comprise a plurality of non-uniform memory access (NUMA) nodes of a single computing device, the local port group for the node comprising ports of the node of the plurality of nodes and the remote port group comprising ports of other nodes of the plurality of nodes.

20. An apparatus comprising:
means for determining numbers of hops for a plurality of paths between a non-uniform memory access (NUMA) node and a storage medium;
means for grouping the paths for the NUMA node based on the determined numbers of hops, the paths being assigned to one of a first group and a second group using an asymmetric logical unit access (ALUA) protocol; and
means for accessing the storage medium using one or more of the paths such that a path of the first group is used before a path of the second port group.

21. The apparatus of claim 20, further comprising means for detecting that the first group is unavailable such that the storage medium is accessed using the second group.

22. The apparatus of claim 20, further comprising means for grouping the paths into different groups for a different NUMA node of the same computing device as the NUMA node, wherein a path of the first group comprises a port marked as optimized using the ALUA protocol and a path of the second group comprises a port marked as non-optimized using the ALUA protocol.
